(19) United States
(12) Patent Application Publication
(10) Pub. No.: US 2015/0244334 A1
(43) Pub. Date: Aug. 27, 2015

(54) AMPLIFICATION DEVICE AND RADIO COMMUNICATION APPARATUS EQUIPPED WITH AMPLIFICATION DEVICE

(71) Applicant: SHARP KABUSHIKI KAISHA, Osaka (JP)

(72) Inventor: Shinji Hara, Osaka-shi (JP)

(73) Assignee: SHARP KABUSHIKI KAISHA, Osaka-shi, Osaka (JP)

(21) Appl. No.: 14/430,967

(22) PCT Filed: Sep. 20, 2013
(86) PCT No.: PCT/JP2013/075429

§ 371 Date: Mar. 25, 2015

(30) Foreign Application Priority Data
Sep. 26, 2012 (JP) 2012-212605

(51) Int. Cl. H03F 3/21; H03F 3/19

(52) U.S. Cl. CPC H03F 3/21; H03F 3/19; H03F 2200/451; H03F 2200/504

(57) ABSTRACT

An amplification transistor has a collector to which a voltage converted by a DC/DC converter is supplied. An output voltage of the DC/DC converter is determined based on an input impedance of a rear-stage circuit block. For example, a voltage of the DC/DC converter is set such that an output waveform of an amplifier circuit becomes appropriate for the input impedance of the rear-stage circuit block (generally 50 [Ω]) in a targeted modulation scheme (mode) or frequency (band) to be used, without having to use an output matching circuit.

### TECHNICAL FIELD

The present invention relates to an amplification device and a radio communication apparatus equipped with the amplification device, and particularly to a technique for amplifying electric power while matching impedances.

### BACKGROUND ART

In a radio communication apparatus such as a mobile phone or a wireless LAN (Local Area Network), the data for communication of audio, data and the like is amplified by a power amplifier, and transmitted to a base station or a communication apparatus on the opposite side.

A microwave frequency is allocated to the above-mentioned type of radio communication, and a power amplifier is adjusted such that it can output a signal of prescribed electric power with a prescribed performance and particularly with prescribed distortion characteristics at a frequency that this power amplifier employs. In an RF circuit used in a microwave, when components having different characteristic impedances are connected, a signal loss resulting from mismatching occurs. Accordingly, in general, an input/output of each component is matched at a characteristic impedance of 50 [Ω], and the power amplifier is also designed so as to achieve the maximum performance at a load of 50[Ω].

Particularly in the case of a mobile phone, however, new standards have been developed year by year in response to an increase in demand for high-speed transmission in accordance with increased volume of data. On each appearance of a new standard, the modulation scheme has been changed. On the other hand, since a radio wave system is different for each country, a common scheme cannot always be used in all areas in the world. Accordingly, old types of standards (modulation schemes) should be indispensably supported. Furthermore, since the frequency to be used is also different for each area and for each carrier, various types of frequencies should also be supported. Therefore, a multimode-capable and multiband-capable terminal is indispensable. Thus, developments are steadily under way such that a baseband IC (Integrated Circuit) and an RFIC (Radio Frequency Integrated Circuit) can be supported.

Meanwhile, a power amplifier, which serves to radiate a radio wave from an antenna, is an important component having performance that exerts an influence upon radio wave characteristics and conformity to regulations, and further upon a consumption current. Accordingly, it is common to use a plurality of power amplifiers optimized to a specific modulation scheme (mode) and a band to be used. An overview of the above-described situations is disclosed in “Nikkei Electronics” (Sep. 6, 2010, pages 29 to 31 and 40 to 47) (NPD 1).

The following is a reason why a power amplifier specialized in a specific modulation scheme and band is commonly used.

FIG. 7 is a block diagram showing a part of the configuration of a portable radio communication apparatus for which a high-frequency power amplifier is used. The portable radio communication apparatus shown in FIG. 7 includes: an antenna 6 for transmitting and receiving data for communication of audio, data and the like by means of radio communication; a switch 7 provided so as to allow antenna 6 to be used for both of transmission and reception; a reception circuit 8 connected to switch 7 and receiving incoming data; and a transmission circuit 9 connected to switch 7 and outputting transmit data.

Transmission circuit 9 has an output unit provided with a high-frequency power amplifier 10 for amplifying a data signal for communication of audio, data and the like. High-frequency power amplifier 10 includes an amplification transistor 1, an output matching circuit 2, and a base bias circuit 4. Amplification transistor 1 is supplied with a voltage from a rechargeable battery 5.

Amplification transistor 1 has: an emitter that is grounded; a collector connected to rechargeable battery 5 through an RF choke coil 3; and a base to which base bias circuit 4 is connected. The electric power input into the base is amplified and output from the collector.

Since the maximum value of the voltage supplied to amplification transistor 1 is limited to the voltage of rechargeable battery 5, an output stage transistor of the amplifier that outputs relatively large power needs to increase a current for achieving required power output. Accordingly, on the output side of the transistor, a relatively low impedance of about several [50] may often be defined as an optimal load. On the other hand, as described above, since the input/output of each component should be matched at a characteristic impedance of 50 [Ω], it is indispensable to provide output matching circuit 2 that performs impedance conversion from about several [Ω] to 50 [Ω].

FIG. 8 shows an example of output matching circuit 2 used in a power amplifier for GSM (registered trademark) (Global System for Mobile Communications) (European digital mobile phone). This output matching circuit 2 converts the output impedance of amplification transistor 1 from 4 [Ω] to 50 [Ω]. Since it is desirable that no loss occurs in output matching circuit 2 of the power amplifier, output matching circuit 2 is formed, without using a resistance, of a reactance, that is, an inductor and a capacitor, or formed of a transmission line for matching. In the example shown in FIG. 8, within a circuit, a chip capacitor is indicated by a reference character C; a chip inductor is indicated by a reference character L, and a transmission line for matching is a microstrip line created on a glass epoxy substrate.

However, since a reactance element has a frequency characteristic, prescribed impedance conversion cannot be implemented in every band, which will be hereinafter described with reference to FIG. 9. FIG. 9 shows a frequency characteristic of an impedance conversion circuit (output matching circuit) shown in FIG. 8. As shown in FIG. 9, assuming that the level of loss regarded as practical is defined at 0.7 dB or less, required performance can be achieved only in a narrow range of 849 MHz to 963 MHz.

A frequency band can be widened, for example, by implementing a multi-staged matching element or the like, but can be generally widened only up to approximately ±10% to ±20% in a specific band, for example, as disclosed in Japanese Patent Laying-Open No. 2011-35761 (PTD 1). Specifically, in terms of the GSM band, GSM 800 and GSM 900 can be implemented by one power amplifier while GSM 1800 and GSM 1900 can be implemented by one power amplifier, with the result that these GSMs can be implemented by a total of two power amplifiers, but all of four bands could not still be implemented by one power amplifier by means of the current techniques.

There are other methods proposed in recent years, by which a matching circuit is switched for each band; a variable capacitance is used for a capacitance within a matching circuit; and the like.

### CITATION LIST

### Patent Document

PTD 1: Japanese Patent Laying-Open No. 2011-35761

### Non Patent Document

NPD 1: “Nikkei Electronics”, Sep. 6, 2010, pages 29 to 31 and 40 to 47

### SUMMARY OF INVENTION

### Technical Problem

As set forth above, in a power amplifier of a type using a conventional matching circuit, it is difficult to deal with required all modes and bands by a single power amplifier. Thus, there are various proposed methods in which: a matching circuit is switched for each band; a variable capacitance is used for a capacitance within a matching circuit; and the like. However, the former method poses disadvantages that: a loss of a changeover switch is added in addition to a normal loss of a matching circuit; a matching circuit is increased in scale; and the like. Furthermore, the latter method also poses a disadvantage that a capacitor array and a control circuit thereof need to be prepared, which leads to an increase in circuit scale.

The present invention has been made in light of the above-described problems, and aims to decrease the size and weight of the device.

### Solution to Problem

An amplification transistor has a collector that is supplied with a voltage converted by a DC/DC converter. The output voltage of the DC/DC converter is determined based on the input impedance of a rear-stage circuit block. For example, the voltage of the DC/DC converter is set such that the output waveform of the amplifier circuit becomes appropriate for the input impedance of the rear-stage circuit block (generally 50 [Ω]) in the targeted modulation scheme (mode) or frequency (band) to be used, without having to use an output matching circuit. Thereby, only a single power amplifier becomes capable of dealing with multimode/multiband. Therefore, the number of required power amplifiers can be reduced, with the result that a terminal is reduced in size.

### BRIEF DESCRIPTION OF DRAWINGS

FIG. 1 is a block diagram showing the configuration of a radio communication apparatus according to the first embodiment.

FIG. 2 is a block diagram showing the configuration of a radio communication apparatus according to the second embodiment.

FIG. 3 is a block diagram showing the configuration of a radio communication apparatus according to the third embodiment.

FIG. 4 is a block diagram showing the configuration of a radio communication apparatus according to the fourth embodiment.

FIG. 5 is a block diagram showing the configuration of a radio communication apparatus according to the fifth embodiment.

FIG. 6 is a block diagram showing the configuration of a radio communication apparatus according to the sixth embodiment.

FIG. 7 is a block diagram showing a part of the configuration of a portable radio communication apparatus using a high-frequency power amplifier.

FIG. 8 is a diagram showing an output matching circuit using a power amplifier for GSM.

FIG. 9 is a diagram showing a frequency characteristic of an impedance conversion circuit (output matching circuit) in FIG. 8.

### DESCRIPTION OF EMBODIMENTS

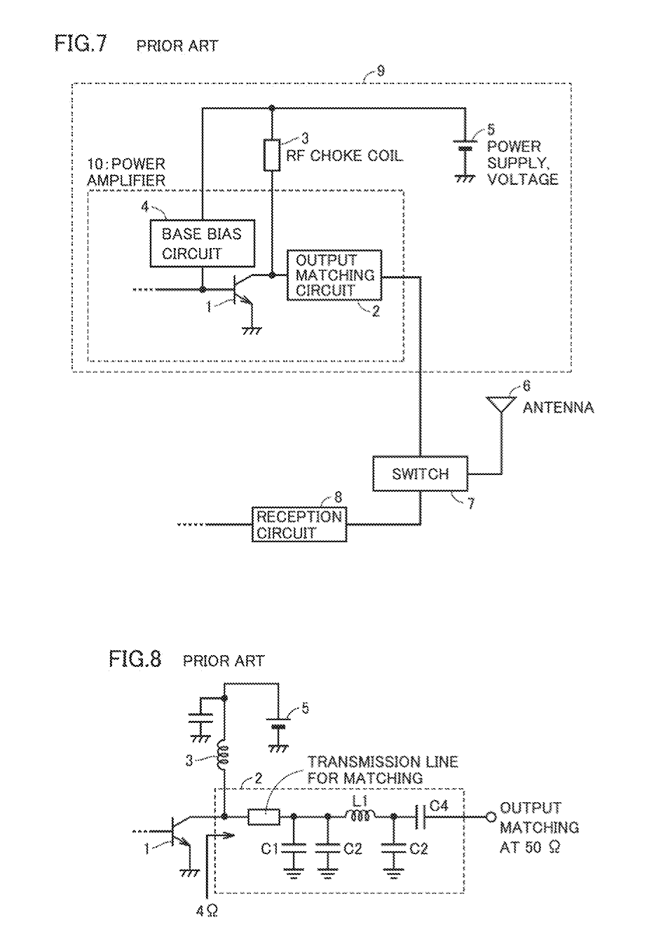

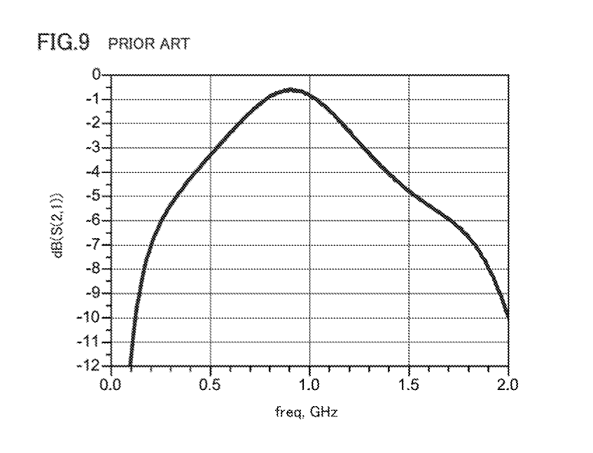

FIG. 1 is a block diagram showing the configuration of the most basic radio communication apparatus using a high-frequency power amplifier of the present invention. It is to be noted that the same types of components as those shown in FIGS. 7 and 8 set forth above will be designated by the same reference characters.

A radio communication apparatus shown in FIG. 1 includes: an antenna 6 for transmitting and receiving data for communication of audio, data and the like by means of radio communication; a switch 7 provided so as to allow antenna 6 to be used for both of transmission and reception; a reception circuit 8 connected to switch 7 and receiving incoming data; a transmission circuit 9 connected to switch 7 and outputting transmit data; and an IC 12 in which a baseband IC and an RFIC are integrally formed. It is to be noted that the baseband IC and the RFIC may be separately provided.

Transmission circuit 9 includes: a high-frequency power amplifier 10 for amplifying a data signal for communication of audio, data and the like; an RF choke coil 3; a voltage variable device (for example, a DC/DC converter) 11; and a rechargeable battery 5 that supplies a voltage to DC/DC converter 11.

High-frequency power amplifier 10 includes an amplification transistor 1 and a base bias circuit 4. Amplification transistor 1 is a compound semiconductor. By way of example, a GaAs HBT (Heterojunction Bipolar Transistor) (gallium arsenide heterojunction bipolar transistor) is used for amplification transistor 1. A GaN (gallium nitride) device may also be used for amplification transistor 1. Furthermore, when forming amplification transistor 1, a switching element forming DC/DC converter 11 may be formed on the same chip.

Amplification transistor 1 has an emitter that is grounded. Amplification transistor 1 has a collector (the output side) connected to DC/DC converter 11 through RF choke coil 3. Amplification transistor 1 has a base to which base bias circuit 4 and IC 12 are connected. An ON signal or an OFF signal is input into base bias circuit 4 from IC 12. The electric power input into the base is amplified and output from the collector.

The voltage output from the collector is determined based on the voltage supplied from DC/DC converter 11 to amplification transistor 1. In other words, high-frequency power amplifier 10 receives electric power at its output side from DC/DC converter 11, uses this electric power to amplify electric power, and outputs the amplified electric power. DC/DC converter 11 converts the voltage supplied from rechargeable battery 5, and supplies the converted voltage to the output side of high-frequency power amplifier 10. By way of example, DC/DC converter 11 converts the voltage supplied from rechargeable battery 5 in accordance with a voltage setting signal input from IC 12, and outputs the converted voltage. Therefore, the output voltage of DC/DC converter 11 can be arbitrarily changed by programming the software executed by IC 12. By way of example, DC/DC converter 11 outputs a voltage higher than the voltage supplied from rechargeable battery 5. In other words, DC/DC converter 11 carries out a voltage raising operation. IC 12 may be programmed such that DC/DC converter 11 carries out a voltage lowering operation.

The voltage supplied to amplification transistor 1, that is, the output voltage of DC/DC converter 11, is determined based on the load (input impedance) of the device connected to the output side of amplification transistor 1. The output voltage of DC/DC converter 11 is set, for example, so as to achieve desired characteristics (distortion, electric power and the like) for a load of 50 [Ω]. Specifically, for example, in order to achieve performance equivalent to that of output matching circuit 2 shown in FIG. 8, DC/DC converter 11 outputs a voltage equivalent to the output voltage of output matching circuit 2.

Electric power P consumed by a load, a load resistance R, and a voltage amplitude V establish the relation represented by P=V²/R. Accordingly, assuming that the operating voltage of output matching circuit 2 in FIG. 8 is V1; the load thereof is R1; the output voltage of DC/DC converter 11 is V2; the load (load of the rear stage circuit in high-frequency power amplifier 10) is R2; and consumption power P remains unchanged, the following formula is approximately realized.

V1²/R1=V2²/R2 (1)

Therefore,

V2=V1×(R2/R1)^{1/2} (2)

In this case, in the case where V1=3.6 [V], R1=4 [Ω] and R2=50 [Ω] in output matching circuit 2 in FIG. 8, the voltage that should be supplied from DC/DC converter 11 to the collector of amplification transistor 1 for achieving the performance equivalent to that of output matching circuit 2 in FIG. 8 is defined as: 3.6 [V]×(50 [Ω]/4 [Ω])^{1/2}≈12.7 [V].

Since transmission circuit 9 in the present embodiment does not include an output matching circuit having a frequency characteristic shown in FIG. 8, transmission circuit 9 of the present embodiment can be operated in a relatively wide band, and thus, the output performance of the output stage transistor is not deteriorated by the frequency characteristics of the matching circuit. Although the optimum load is different for each mode or band, the theory similar to that described above is used to adjust the voltage value for dealing with various loads, thereby allowing every mode and every band to be addressed.

Furthermore, the operating voltage is raised, thereby achieving an effect that a loss is secondarily reduced. For example, as disclosed in Japanese Patent Laying-Open No. 2007-19585, a reactance element used for a matching circuit actually includes a resistance component, with the result that the matching circuit is increased in loss as the conversion ratio is increased. Since the present invention does not include a matching circuit, it also has a characteristic that a loss thereof does not occur.

Furthermore, in addition to the advantage that size reduction can be achieved due to having no matching circuit, the present invention also has an advantage that the transistor to be used can be reduced in area since the current value is decreased by a high voltage operation.

On the other hand, although DC/DC converter 11 is required, this requirement cannot necessarily be a disadvantage when comparatively considering the effect that the number of power amplifiers is reduced. In addition, also employed in a mobile phone is a method of lowering a power supply voltage using a DC/DC converter at the time when the output power is relatively small (for example, Japanese Patent Laying-Open No. 2001-257540). Accordingly, it is not disadvantageous that DC/DC converter 11 is required.

Furthermore, power consumption can be further reduced by employing a method in which a voltage value regarded as a reference is raised, for example, to 12.7 [V] in an example in FIG. 1 and, when the output is relatively small, the voltage is accordingly lowered to approximately 5 [V].

Furthermore, the frequency band or the modulation standard of a mobile phone may by determined utilizing well-known techniques, and then, based on the determined frequency band or modulation standard, the output voltage of DC/DC converter 11 may be set in accordance with the voltage table stored in a memory in advance.

Furthermore, a part of the output from power amplifier 10 may be branched off or the like to monitor the output waveform of power amplifier 10, and then, DC/DC converter 11 may be feedback-controlled such that the monitored output waveform satisfies prescribed requirements.

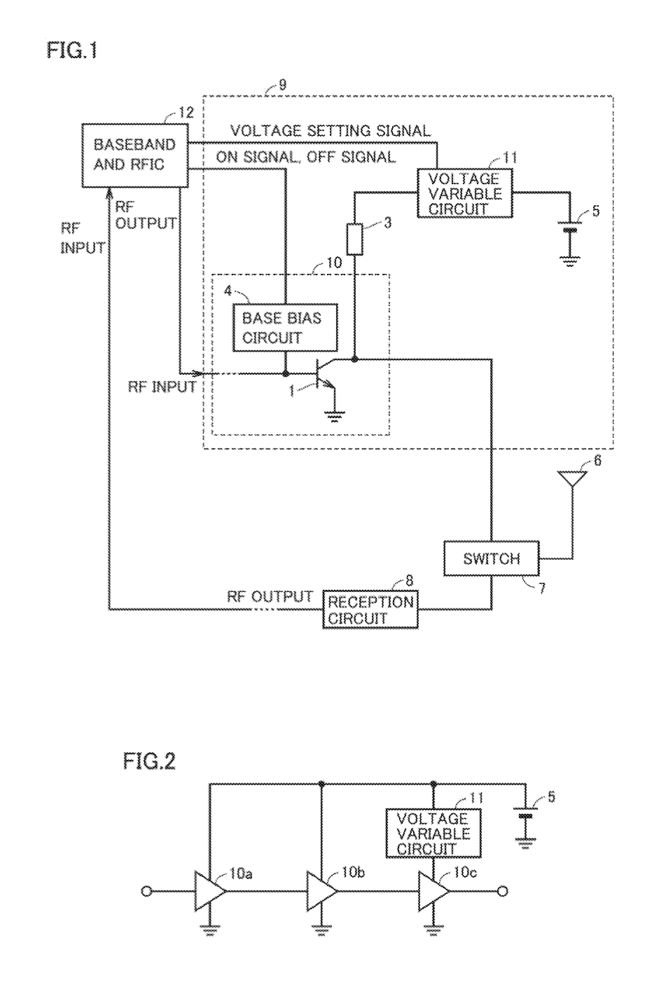

FIG. 2 shows the second embodiment. In the present embodiment, a multistage amplifier consisting of power amplifiers 10a to 10c is employed as compared with FIG. 1. It is to be noted that the number of power amplifiers is not limited to three. Since the performance of power amplifier 10c at the last stage is dominant in this multistage amplifier, DC/DC converter (voltage variable circuit) 11 is applied only to the last stage and the driver stage is directly connected to rechargeable battery 5.

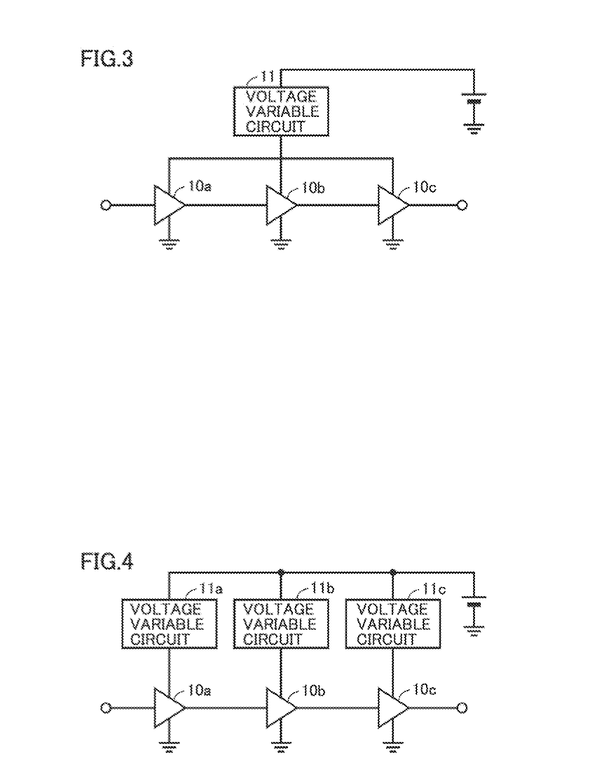

FIG. 3 shows the third embodiment. In the present embodiment, DC/DC converter (voltage variable circuit) 11 is applied to each stage of a multistage amplifier while the power supply voltages at all stages of the multistage amplifier are uniformly controlled.

FIG. 4 shows the fourth embodiment. In the present embodiment, DC/DC converters (voltage variable circuits) 11a to 11c are applied to stages, respectively, of a multistage amplifier while the power supply voltage at each of these stages of the multistage amplifier is independently controlled. This allows more sophisticated adjustment of characteristics.

FIG. 5 shows the fifth embodiment. In the present embodiment, the bias voltages of power amplifiers 10a to 10c can also be changed by variable bias circuits 12a to 12c, respectively, as compared with the embodiment in FIG. 4. The power amplifier in recent years is required to exhibit such a performance as having low distortion characteristics and low power-consumption characteristics that are opposed to each other, to which the setting of the bias voltage is significantly related. Therefore, in contrast to the first to fourth embodiments, not only the power supply voltage but also the bias voltage is changed in accordance with the mode and band to be used and also with the output power, with the result that the performance can be further improved.

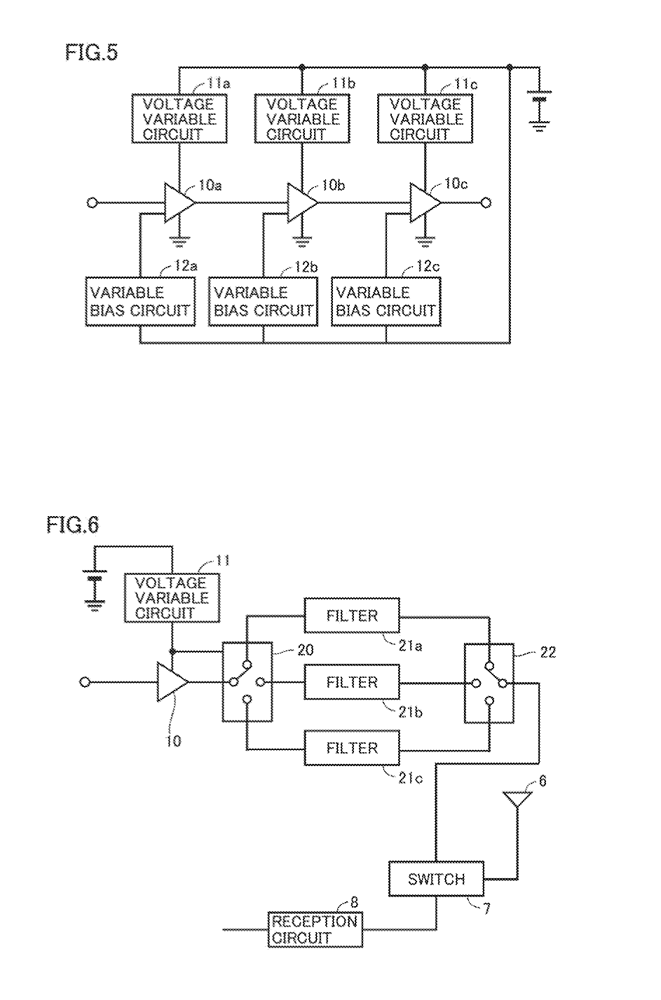

FIG. 6 shows the sixth embodiment of the present invention. In the present embodiment, a path changeover switch 20 and a switch 22 are additionally provided at the output of power amplifier 10 that has been described as above. By way of example, a GaAs HEMT (High Electron Mobility Transistor) (gallium arsenide high-electron mobility transistor) is often used for path changeover switch 20. Also, GaN may be used as a material of path changeover switch 20.

Path changeover switch 20 changes the supply destination of the electric power output from power amplifier 10. By way of example, as shown in FIG. 6, the filter to which electric power is supplied is selected from a plurality of filters 21a to 21c provided for each frequency band. It is to be noted that the number of filters is not limited to three, but any number of filters may be provided as long as the number thereof is more than one. The filter connected to switch 7 is switched by switch 22. More specifically, the filter receiving electric power from power amplifier 10 is connected to switch 7.

In a mobile phone, the output load that path changeover switch 20 obtains is 50 [Ω], for example. The bias voltage of path changeover switch 20 is applied directly from a battery, or applied from a 2.7 [V] or 3 [V] power supply stabilized at LDO (Low Drop Out). Therefore, as in the case of power amplifier 10, the gate width needs to be increased so as to allow a large current to be handled in order to switch large electric power without causing distortion. In addition to the problem that a chip size is increased in accordance with an increase in gate width, there also occurs a problem that the stray capacitance of the transistor is increased to cause deterioration in isolation characteristics or frequency characteristics of insertion loss. However, by using a voltage-raising power supply similar to that of power amplifier 10 also for the bias of path changeover switch 20, the gate width can be decreased when the same electric power is applied, so that the above-described problems can be solved.

Furthermore, by way of example, a MOSFET (Metal-Oxide-Semiconductor Field-Effect Transistor) is used for a switching element of DC/DC converter 11. In this case, since the operation frequency is several MHz, an external inductor is relatively large in size, thereby causing a problem that size reduction becomes difficult. However, a compound semiconductor that can operate at a high speed operation is used for a switching element of DC/DC converter 11, thereby allowing switching at several tens of MHz, so that a variable voltage source itself can be reduced in size.

It should be construed that embodiments disclosed herein are by way of illustration in all respects, not by way of limitation. The scope of the present invention is defined by the terms of the claims, rather than the description above, and is intended to include any modifications within the meaning and scope equivalent to the terms of the claims.

### REFERENCE SIGNS LIST

1 amplification transistor, 2 output matching circuit, 3 choke coil, 4 base bias circuit, 5 rechargeable battery, 6 antenna, 7 switch, 8 reception circuit, 9 transmission circuit, 10 high-frequency power amplifier, 11, 11a, 11b, 11c voltage variable circuit (DC/DC converter), 12 IC, 12a, 12b, 12c variable bias circuit, 20 path changeover switch, 21a, 21b, 21c filter.

1. An amplification device comprising:
a power amplifier configured to receive electric power at an output side, use the received electric power to amplify electric power, and output the amplified electric power; and
a variable voltage circuit configured to convert a voltage supplied from a power supply and supply the converted voltage to the output side of said power amplifier,
an output voltage of said variable voltage circuit being determined based on an impedance of a device connected to the output side of said power amplifier.

2. The amplification device according to claim 1, further comprising a controller configured to cause said variable voltage circuit to output a prescribed voltage in accordance with a program.

3. The amplification device according to claim 1, further comprising a controller configured to cause said variable voltage circuit to output a prescribed voltage in accordance with an operation state of an apparatus equipped with said amplification device.

4. The amplification device according to claim 1, wherein the output voltage of said variable voltage circuit is higher than the voltage supplied from said power supply.

5. The amplification device according to claim 1, wherein
said power amplifier includes a transistor, and
said amplification device further comprises a variable bias voltage circuit that changes a bias voltage of said transistor.

6. The amplification device according to claim 1, further comprising a switch that changes a supply destination of the electric power output from said power amplifier.

7. The amplification device according to claim 6, wherein
said power amplifier includes a transistor, and
said switch is made of a material that is the same as a material of said transistor.

8. The amplification device according to claim 1, wherein said power amplifier is a compound semiconductor.

9. The amplification device according to claim 8, wherein said power amplifier includes a heterojunction bipolar transistor formed of gallium arsenide.

10. The amplification device according to claim 8, wherein said power amplifier includes a transistor formed of gallium nitride.

11. The amplification device according to claim 1, wherein
said variable voltage circuit is formed of a switching element, and
said switching element is a compound semiconductor.

12. The amplification device according to claim 11, wherein said switching element is made of gallium nitride.

13. The amplification device according to claim 11, wherein
said power amplifier includes a transistor, and
said transistor and said switching element are formed on a single chip.

14. A radio communication apparatus equipped with the amplification device according to claim 1.
